(19) United States
(12) Patent Application Publication
(10) Pub. No.: US 2019/0207063 A1
(43) Pub. Date: Jul. 4, 2019

(54) LIGHT EMITTING DEVICE

(71) Applicant: LUMENS CO., LTD., Yongin-si (KR)

(72) Inventors: Byeonggeon KIM, Yongin-si (KR); Sungsik JO, Yongin-si (KR)

(73) Assignee: LUMENS CO., LTD., Yongin-si (KR)

(21) Appl. No.: 16/224,325

(22) Filed: Dec. 18, 2018

(30) Foreign Application Priority Data
Dec. 29, 2017 (KR) 10-2017-0183393

(51) Int. Cl. H01L 33/50; H01L 33/60

(52) U.S. Cl. CPC H01L 33/504; H01L 33/486; H01L 33/507; H01L 33/60

(57) ABSTRACT

A light emitting device is disclosed. The light emitting device includes: an LED chip outputting excitation light; first converting materials receiving the excitation light to output light having a first peak intensity; second converting materials receiving the excitation light to output light having a second peak intensity and absorbing non-radiative energy from the first converting materials to output light having a third peak intensity higher than the second peak intensity when excited together with the first converting materials by the excitation light; and a light transmitting member transmitting light in a wavelength region corresponding to the third peak intensity and blocking light in the other wavelength regions.

### BACKGROUND OF THE INVENTION

### 1. Field of the Invention

The present invention relates to light emitting devices, and more particularly to light emitting devices capable of outputting light at a specific wavelength, particularly in a red wavelength region with high efficiency.

### 2. Description of the Related Art

Various types of wavelength converting materials capable of converting the wavelengths of light from LEDs are used to utilize the LEDs in various applications, including display or lighting. Phosphors have been used as wavelength converting materials. In recent years, the use of quantum dots (QDs) capable of emitting light at various wavelengths depending on their size or shape has been steadily on the rise.

Red LEDs are required to apply LEDs to specific fields, including displays. However, different voltage characteristics of red LEDs based on AlGaAS, GaAs, AlGaInP or GaP and blue and green LEDs based on GaN/InGaN make it unsuitable to use the red LED in combination with the blue and green LEDs in the same display. Research has been conducted recently on micro-LED displays in which blue LED chips, green LED chips, and red LED chips constitute pixels on the same substrate. However, it is difficult to arrange the red LED chips with the blue LED chips and the green LED chips on the same substrate because the material of the red LED chips is different from the materials of the blue LED chips and the green LED chips.

Under these circumstances, there has been research aimed at developing light emitting devices which include an excitation light source emitting blue light, a phosphor converting the wavelength of a portion of the light from the excitation light source such that the blue light is mixed with the wavelength-converted light to emit white light, and a color filter extracting red light from the white light. However, a significant portion of the light is lost in the light emitting devices, making the light emitting devices inefficient. To overcome this fatal drawback, the use of an increased amount of red fluorescent materials was considered. Disadvantageously, particles of the red fluorescent materials tend to agglomerate.

### SUMMARY OF THE INVENTION

Therefore, the present invention has been made in view of the above problems, and it is an object of the present invention to provide light emitting devices that use wavelength converting materials receiving excitation light from an LED chip to provide non-radiative energy in combination with wavelength converting materials absorbing the non-radiative energy to output light in a specific wavelength region with higher intensity, achieving higher output efficiency of the light at the specific wavelength.

A light emitting device according to one aspect of the present invention includes: an LED chip outputting excitation light; first converting materials receiving the excitation light to output light having a first peak intensity; second converting materials receiving the excitation light to output light having a second peak intensity and absorbing non-radiative energy from the first converting materials to output light having a third peak intensity higher than the second peak intensity when excited together with the first converting materials by the excitation light; and a light transmitting member transmitting light in a wavelength region corresponding to the third peak intensity and blocking light in the other wavelength regions.

According to one embodiment, the first converting materials output light having a fourth peak intensity lower than the first peak intensity when excited together with the second converting materials by the excitation light.

According to one embodiment, the third peak intensity is higher than the fourth peak intensity.

According to one embodiment, the excitation light is UV or blue light and the first converting materials output blue or green light when excited by the excitation light.

According to one embodiment, the excitation light is UV or blue light and the second converting materials output red light when excited by the excitation light.

According to one embodiment, the first converting materials include donor quantum dots outputting green or blue light when excited by the excitation light and the second converting materials include acceptor quantum dots outputting red light when excited by the excitation light.

According to one embodiment, the distance between the donor quantum dots and the acceptor quantum dots is from 10 to 100 Å.

According to one embodiment, the first converting materials are mixed with the second converting materials in a light transmitting resin part.

According to one embodiment, the shift distance from a peak wavelength corresponding to the second peak intensity to a peak wavelength corresponding to the third peak intensity is between 5 nm and 15 nm.

According to one embodiment, the shift distance from the peak wavelength corresponding to the second peak intensity to the peak wavelength corresponding to the third peak intensity is at least 1.5 times smaller than that from a peak wavelength corresponding to the first peak intensity to a peak wavelength corresponding to the fourth peak intensity.

According to one embodiment, the difference between the first peak intensity and the fourth peak intensity is larger than that between the third peak intensity and the second peak intensity.

According to one embodiment, the light emitting device further includes: a reflector having a cavity in which the LED chip is accommodated; a wavelength converting panel including a lower glass plate, an upper glass plate, and a wavelength converting layer including the second converting materials and the first converting materials and interposed between the lower glass plate and the upper glass plate; and a sealing member disposed over the side surface of the lower glass plate and the side surface of the upper glass plate to connect the wavelength converting panel to the reflector.

According to one embodiment, the light emitting device further includes a light shield wall having a vertical hole wherein the LED chip is accommodated in a lower portion of the vertical hole and the wavelength converting layer including the mixture of the second converting materials and the first converting materials is arranged above the LED chip inside the vertical hole.

According to one embodiment, the light emitting device further includes a light shield wall having a vertical hole wherein the LED chip is accommodated in a lower portion of the vertical hole, the light transmitting member is arranged in an upper portion of the vertical hole, and the wavelength converting layer including the mixture of the second converting materials and the first converting materials is interposed between the LED chip and the light transmitting member inside the vertical hole.

According to one embodiment, the light transmitting member is a color filter absorbing or blocking light other than the light in the wavelength region corresponding to the third peak intensity.

A light emitting device according to a further aspect of the present invention includes: an LED chip outputting excitation light; first converting materials receiving the excitation light to output light having a first peak intensity; and second converting materials receiving the excitation light to output light having a second peak intensity and absorbing non-radiative energy from the first converting materials to output light having a third peak intensity higher than the second peak intensity when excited together with the first converting materials by the excitation light, wherein the first converting materials output light having a fourth peak intensity lower than the first peak intensity when excited together with the second converting materials by the excitation light.

According to one embodiment, the light emitting device further includes a light transmitting member transmitting light in a wavelength region corresponding to the third peak intensity and absorbing or reflecting light in the other wavelength regions.

According to one embodiment, the third peak intensity is higher than the fourth peak intensity.

According to one embodiment, the excitation light is UV or blue light and the first converting materials output blue or green light when excited by the excitation light.

According to one embodiment, the excitation light is UV or blue light and the second converting materials output red light when excited by the excitation light.

In the light emitting devices of the present invention, the wavelength converting materials receiving excitation light from the LED chip to provide non-radiative energy are used in combination with the wavelength converting materials absorbing the non-radiative energy to output light in a specific wavelength region with higher intensity, achieving higher output efficiency of the light at the specific wavelength. Other advantages and effects of the present invention will be better understood from the following description of the embodiments.

### BRIEF DESCRIPTION OF THE DRAWINGS

FIG. 1 is a cross-sectional view illustrating a light emitting device according to one embodiment of the present invention.

FIG. 2 illustrates the luminescent properties of a wavelength converting member including first converting materials and second converting materials.

FIG. 3 is a cross-sectional view illustrating a light emitting device according to a further embodiment of the present invention.

FIG. 4 is a cross-sectional view illustrating a light emitting device according to another embodiment of the present invention.

### DETAILED DESCRIPTION OF THE INVENTION

Embodiments of the present invention will now be described in detail with reference to the accompanying drawings. These embodiments are provided so that this disclosure will be thorough and complete, and will fully convey the scope of the invention to those skilled in the art. Accordingly, the present invention may be embodied in many different forms and should not be construed as limited to the exemplary embodiments set forth herein. In the drawings, the dimensions, such as widths, lengths and thicknesses, of elements may be exaggerated for clarity. The same reference numerals denote the same elements throughout the specification.

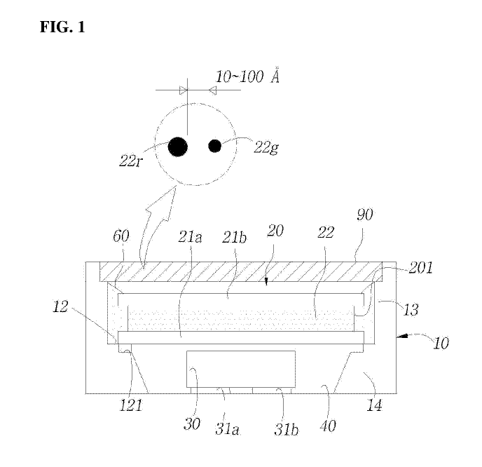

Referring to FIG. 1, a light emitting device according to one embodiment of the present invention includes a metal reflector 10 having a ring-shaped stepped portion 12 (hereinafter referred to as “first stepped portion”) formed in the middle of the height of the inner wall surface thereof along the inner wall surface, a wavelength converting panel 20 arranged in an inner upper space of the reflector 10 to be supported by the first stepped portion 12, an LED chip 30 accommodated in an inner lower space of the reflector 10 and located below the wavelength converting panel 20, and a resin reflective wall 40 disposed in the inner lower space of the reflector 10 to cover the upper surface and the side surface of the LED chip 30.

The light emitting device includes a metal sealing member 60 closing the edge of the wavelength converting panel 20 to prevent moisture from infiltrating into internal wavelength converting materials and to thermally connect the wavelength converting panel 20 to the metal reflector 10. The light emitting device includes a light transmitting member 90 selectively transmitting only light in a red wavelength region among light entering through the wavelength converting panel 20 and blocking light in the other wavelength regions by reflection or absorption.

The LED chip 30 emits blue excitation light to excite wavelength converting materials present in the LED chip 30. Alternatively, a UV LED chip may be used as a light source to excite the wavelength converting materials.

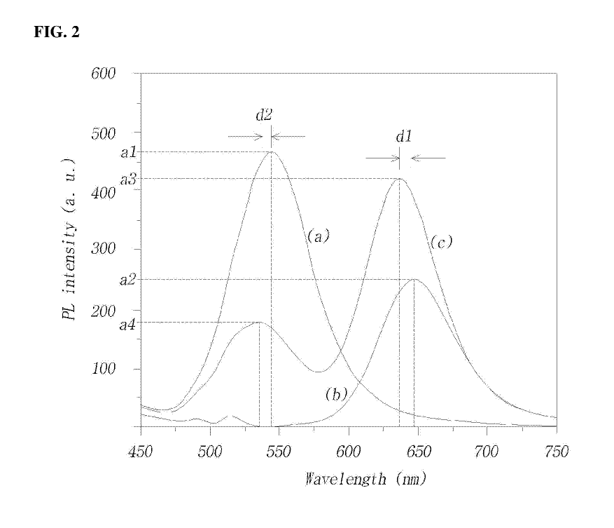

The wavelength converting panel 20 includes a light transmitting lower glass plate 21a, a light transmitting upper glass plate 21b, and a wavelength converting layer 22 interposed between the lower glass plate 21a and the upper glass plate 21b. The wavelength converting layer 22 includes green quantum dots 22g as first converting materials and red quantum dots 22r as second converting materials. It is noted that blue quantum dots may be used as the first converting materials instead of green quantum dots. The wavelength converting layer 22 is formed by mixing the green quantum dots 22g and the red quantum dots 22r in a light transmitting resin. The distance between the green quantum dots 22g and the red quantum dots 22r is determined to be as close as possible within 10 to 100 Å. More specifically, the emission wavelength region of the green or blue quantum dots as the second converting materials is within the excitation wavelength range of the red quantum dots as the first converting materials, the green or blue quantum dots and the red quantum dots are blended together in a resin to obtain an intended spectral distribution curve (see (c) of FIG. 2), and the wavelength converting layer 22 is arranged in the path of excitation light from the LED chip 30.

When the green quantum dots 22g as the first converting materials are close to the red quantum dots 22r as the second converting materials, emission and absorption regions overlap in their spectral distribution curves. Based on the principle of fluorescence resonance energy transfer (FRET), the green quantum dots 22g as the first converting materials excited by excitation light from the LED chip 30 absorb energy from the LED chip 30, the absorbed energy is not emitted in the form of light but is transferred in the form of non-radiative energy to the red quantum dots 22g as the second converting materials, and the red quantum dots 22r radiate red light in a higher wavelength region with higher intensity.

The light transmitting member 90 transmits only red light among light entering through the wavelength converting panel 20 and blocks light in the other wavelength regions. Since the majority of light entering through the wavelength converting panel 20 is converted to red light based on the FRET principle, the amount of light blocked by the light transmitting member 90 can be minimized. The light transmitting member 90 is preferably a distributed Bragg reflector (DBR) designed to transmit light in a red wavelength region corresponding to the third peak intensity therethrough or a color filter designed to absorb or block light other than light in a red wavelength region corresponding to the third peak intensity.

In addition, the light emitting device may further include a metal plating layer (not illustrated) covering both the metal reflector 10 and the metal sealing member 60 to integrate the metal reflector 10 with the metal sealing member 60.

FIG. 2 illustrates the luminescent properties of the first converting materials and the second converting materials used in the light emitting device of the present invention.

In FIG. 2, (a) is a spectral distribution curve of the first converting materials excited alone by excitation light from the LED chip, (b) is a spectral distribution curve of the second converting materials excited alone by excitation light from the LED chip, and (c) is a spectral distribution curve of the first converting materials and the second converting materials excited by excitation light from the LED chip.

As shown from the spectral distribution curve (a) of FIG. 2, the first converting materials output green light at a peak wavelength of about 543 nm corresponding to a first peak intensity a1 when excited alone by excitation light. The first peak intensity a1 is approximately 470 a.u.

As shown from the spectral distribution curve (b) of FIG. 2, the second converting materials output red light at a peak wavelength of about 648 nm corresponding to a second peak intensity a2 lower than the first peak intensity a1 when excited alone by excitation light. The second peak intensity a1 is approximately 250 a.u.

As shown from the spectral distribution curve (c) of FIG. 2, the second converting materials absorb non-radiative energy from the converting materials and output red light at a peak wavelength of about 637 nm corresponding to a third peak intensity a3 when excited together with the first converting materials by the excitation light, and the first converting materials output green light at a peak wavelength of about 535 nm corresponding to a fourth peak intensity a4 when excited together with the second converting materials by the excitation light. In this embodiment, the third peak intensity a3 is approximately 420 a.u. and the fourth peak intensity a4 is approximately 179 a.u.

The second converting materials absorbing non-radiative energy from the first converting materials can output light with the third peak intensity a3 higher than the second peak intensity a2 when excited alone. In contrast, the first converting materials transmitting non-radiative energy to the second converting materials can output light with the fourth peak intensity a4 lower than the first peak intensity a1 when excited alone. The higher third peak intensity a3 than the fourth peak intensity a4 indicates that the generation of red light increases and the generation of unnecessary green light can be eventually minimized.

The large size of the red quantum dots as the second converting materials is advantageous in receiving non-radiative energy from the small-sized green quantum dots, including small-sized blue quantum dots, to output red light. For this reason, it is preferred to adjust the second peak intensity a2 to have a lower value than the first peak intensity a1. This adjustment can be accomplished by the amount and particle size of the green quantum dots as the first converting materials, the amount and particle size of the red quantum dots as the second converting materials, and the distance between the red quantum dots and the green quantum dots. The distance between the donor quantum dots and the acceptor quantum dots is preferably from 10 to 100 Å. If the distance exceeds 100 Å, an insignificant amount of non-radiative energy is transferred from the first converting materials to the second converting materials, and as a result, high efficiency cannot be expected.

The shift distance d1 from the red peak wavelength corresponding to the second peak intensity a2 to the red peak wavelength corresponding to the third peak intensity a3 is advantageously from 5 to 15 nm. Furthermore, the shift distance d1 from the peak wavelength corresponding to the second peak intensity a2 to the peak wavelength corresponding to the third peak intensity a3 is preferably at least 1.5 times smaller than the shift distance d2 from the peak wavelength corresponding to the first peak intensity a1 to the peak wavelength corresponding to the fourth peak intensity a4. Each of the shift directions is preferably a direction toward decreasing wavelength. That is, the shift directions are negative (−) directions. If d1 exceeds 1.5 times the shift distance d2 or exceeds 15 nm, red light with the desired color temperature cannot be obtained.

In order for the red quantum dots as the second converting materials to receive the largest possible amount of non-radiative energy from the green quantum dots as the first converting materials, it is advantageous that the difference between the first peak intensity and the fourth peak intensity is larger than the difference between the third peak intensity and the second peak intensity.

Referring back to FIG. 1, the metal sealing member 60 of the light emitting device closes the edge of the wavelength converting panel 20 to prevent moisture from infiltrating into the internal wavelength converting materials and to thermally connect the wavelength converting panel 20 to the metal reflector 10.

The metal reflector 10 may be made of a highly thermally conductive and reflective metal, preferably nickel, chromium, silver, aluminum, gold, copper, zinc, tin, platinum or lead, or a metal material including at least one of these metals. The metal reflector 10 is divided into an upper space and a lower space by the first stepped portion 12. The upper space is surrounded by an upper wall 13 extending vertically upward from the outer edge of the first stepped portion 12 and the lower space is surrounded by a lower wall 14 extending obliquely downward from the inner edge of the first stepped portion 12.

A second stepped portion 121 is connected to the overlying first stepped portion 12. More specifically, the second stepped portion 121 is formed along the boundary between the inner edge of the first stepped portion 12 and the upper end of the lower wall 14. The upper surface of the first stepped portion 12 and the upper surface of the second stepped portion 121 are preferably horizontal.

The wavelength converting panel 20 is constructed by applying a first solid polymer between the upper surface of the lower glass plate 21a and the lower surface of the wavelength converting layer 22 and between the lower surface of the upper glass plate 21b and the upper surface of the wavelength converting layer 22 and melting the first solid polymer. In the wavelength converting panel 20, the lower glass plate 21a is integrated with the upper glass plate 21b through the wavelength converting layer 22. The first solid polymer may be a glass molding material, an epoxy resin or a silicone resin.

The wavelength converting layer 22 has an area smaller than the area of the lower glass plate 21a and the area of the upper glass plate 21b. With these dimensions, a recess 201 is formed along the edge of the wavelength converting panel 20. The recess 201 is depressed more inwardly than the side surface of the lower glass plate 21a and the side surface of the upper glass plate 21b.

The wavelength converting panel 20 is horizontally situated on the first stepped portion 12. Here, the edge of the lower surface of the wavelength converting panel 20 (more specifically the lower glass plate 21a) is in contact with the first stepped portion 12 and a gap exists between the side surface of the wavelength converting panel 20 and the upper wall 13 of the metal reflector 10.

Here, the side surface of the wavelength converting sheet 22 of the wavelength converting panel 20 faces the upper wall 13 of the metal reflector 10 through the gap. Another gap is formed between a portion of the lower surface of the wavelength converting panel 20 and the first stepped portion 12 by the second stepped portion 121 formed under the first stepped portion 12.

As mentioned earlier, the LED chip 30 is accommodated in the inner lower space of the reflector 10 that is open downward. The LED chip 30 is located below the wavelength converting panel 20. The LED chip 30 is integrated with the metal reflector 10 through the resin reflective wall 40 disposed in the inner lower space of the reflector 10 to cover the upper surface and the side surface of the LED chip 30. The resin reflective wall 40 may be a white wall formed by mixing amorphous spherical silica with a resin to obtain a white resin, filling the white resin in the inner lower space of the metal reflector 10, and curing the white resin. The LED chip 30 may be one that emits light at a short wavelength. For example, the LED chip 30 may be a blue or UV LED chip. The LED chip 30 is preferably a flip-chip type LED chip having a pair of electrode pads with opposite polarities at the lower side thereof. The pair of electrode pads 31a and 31b are exposed to the outside through an opening formed at the lower end of the reflector 10. When the LED package is mounted on a PCB, the pair of electrode pads 31a and 31b are bonded to electrodes disposed on the PCB. The bottom surfaces of the pair of electrode pads 31a and 31b lie at the same level as the bottom surface of the metal reflector 10 and the bottom surface of the resin reflective wall 40. This arrangement prevents light emitted from the LED chip 30 from leaking through the bottom of the reflector 10 to the outside.

The QDs or phosphor particles present in the wavelength converting layer 22 convert the wavelength of light emitted from the LED chip. The wavelength-converted light is emitted from the wavelength converting layer 22. Preferably, the lower wall 14 of the reflector 10 has a downwardly tapered inner side surface. Due to this shape, the resin reflective wall 40 is prevented from easily escaping from the lower space.

The metal sealing member 60 is formed by filling a thermally conductive metal in the form of a liquid (or paste) or powder in the gap between the inner wall surface of the metal reflector 10 and the wavelength converting panel 20 supported by the first stepped portion 12 of the metal reflector 10 and solidifying the thermally conductive metal. The metal sealing member 60 is formed in contact with the side surfaces of the lower glass plate 21a and the upper glass plate 21b to fill the recess 201 formed along the edge of the wavelength converting panel 20 and close the edge of the wavelength converting panel 20. The metal sealing member 60 is formed in contact with the inner side surface of the upper wall 13 of the metal reflector 10. With this arrangement, heat transferred to the wavelength converting panel 20 can be released to the outside through the metal sealing member 60 and the metal reflector 10. A Pt paste can be advantageously used as a material for the formation of the metal sealing member 60. Alternatively, a metal such as nickel, chromium, silver, aluminum, gold, copper, zinc, tin, platinum or lead, or a metal material including at least one of these metals may be used to form the metal sealing member 60.

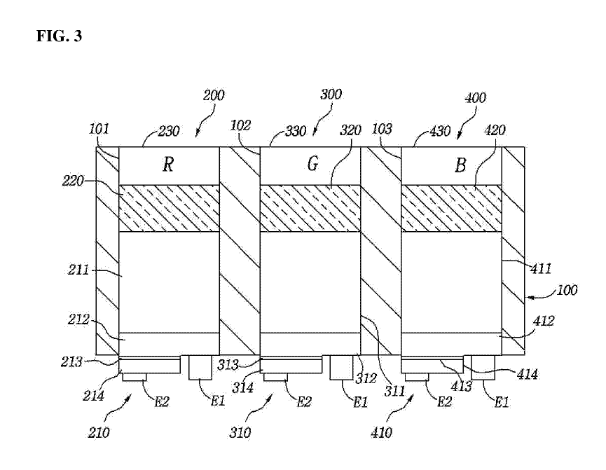

FIG. 3 illustrates a light emitting device according to a further embodiment of the present invention.

Referring to FIG. 3, the light emitting device essentially includes a light shield wall 100 and first, second, and third light emitting units 200, 300, and 400. The light shield wall 100 includes upper and lower surfaces parallel to each other. A first vertical hole 101, a second vertical hole 102, and a third vertical hole 103 are formed in parallel to one another from the upper surface to the lower surface of the light shield wall 100. The light shield wall 100 surrounds the side surfaces of the first, second, and third light emitting units 200, 300, and 400, each of which has a cuboid shape. Thus, the first vertical hole 101, the second vertical hole 102, and the third vertical hole 103 are substantially quadrangular in cross section.

The first light emitting unit 200 is arranged to fill the first vertical hole 101. The first light emitting unit 200 includes a first light transmitting member 230 arranged in the upper portion of the inner space of the first vertical hole 101, a first LED chip 210 arranged at a vertical position below the first light transmitting member 230, and a first wavelength converting member 220 interposed between the first light transmitting member 230 and the first LED chip 210.

The second light emitting unit 300 is arranged to fill the second vertical hole 102. The second light emitting unit 300 includes a second light transmitting member 330 arranged in the upper portion of the inner space of the second vertical hole 102, a second LED chip 310 arranged at a vertical position below the second light transmitting member 330, and a second wavelength converting member 320 interposed between the second light transmitting member 330 and the second LED chip 310.

The third light emitting unit 400 is arranged to fill the third vertical hole 103. The third light emitting unit 400 includes a third light transmitting member 430 arranged in the upper portion of the inner space of the third vertical hole 103, a third LED chip 410 arranged at a vertical position below the third light transmitting member 430, and a third wavelength converting member 420 interposed between the third light transmitting member 430 and the third LED chip 410.

The second LED chip 310 and the third LED chip 410 emit light in respective blue wavelength regions. Each of the second wavelength converting member 320 and the third wavelength converting member 420 includes one or more types of quantum dots or phosphors. The second wavelength converting member 320 and the third wavelength converting member 420 convert the wavelength of blue light from the second LED chip 310 and the third LED chip 410, respectively, and mix the wavelength-converted light with non-converted light to produce white light. The second light transmitting member 330 separates only green light from the white light obtained by the combination of the second LED chip 310 and the second wavelength converting member 320 and allows the separated light to pass therethrough. The third light transmitting member 430 separates only green light from the white light obtained by the combination of the third LED chip 410 and the third wavelength converting member 420 and allows the separated light to pass therethrough.

The first LED chip 210 emits light in a blue wavelength region. The first wavelength converting member 220 is a wavelength converting layer including first converting materials and second converting materials excited by the first LED chip 210. The first wavelength converting member 220 includes green quantum dots as the first converting materials and red quantum dots as the second converting materials. It is noted that blue quantum dots may be used as the first converting materials instead of green quantum dots. The first wavelength converting member 220 is preferably a layer formed by mixing green quantum dots as the first converting materials and red quantum dots as the second converting materials in a light transmitting resin. The distance between the green quantum dots and the quantum dots is determined to be as close as possible within 10 to 100 Å, like in the previous embodiment. When the green quantum dots as the first converting materials are close to the red quantum dots as the second converting materials, emission and absorption regions overlap in their spectral distribution curve. Based on the principle of fluorescence resonance energy transfer (FRET), the green quantum dots as the first converting materials excited by excitation light from the LED chip 210 absorb energy from the LED chip, the absorbed energy is not emitted in the form of light but is transferred in the form of non-radiative energy to the red quantum dots as the second converting materials, and the red quantum dots radiate red light in a higher wavelength region with higher intensity. The light transmitting member 230 transmits only red light among light entering through the wavelength converting panel 220 and blocks light in the other wavelength regions. Since the majority of light entering through the wavelength converting panel 220 is converted to red light based on the FRET principle, the amount of light blocked by the light transmitting member 220 can be minimized. The selective first light transmitting member 230 is preferably a distributed Bragg reflector (DBR) designed to transmit light in a red wavelength region corresponding to the third peak intensity therethrough or a color filter designed to absorb or block light other than light in a red wavelength region corresponding to the third peak intensity.

The constitutions and functions of the donor materials and the second converting materials in the light emitting device including the first LED chip 210, the first wavelength converting member 220, and the selective first light transmitting member 230 are the same as described above with reference to FIGS. 1 and 2, and their repeated explanation is omitted to avoid duplication.

According to this embodiment, the first LED chip 210 includes a light emitting surface in contact with the first wavelength converting member 220 and a pad forming surface exposed to the outside through the bottom of the first vertical hole 101, the second LED chip 310 includes a light emitting surface in contact with the second wavelength converting member 320 and a pad forming surface exposed to the outside through the bottom of the second vertical hole 102, and the third LED chip 410 includes a light emitting surface in contact with the third wavelength converting member 420 and a pad forming surface exposed to the outside through the bottom of the third vertical hole 103.

The first LED chip 210, the second LED chip 310, and the third LED chip 410 include first conductive electrode pads E1 and second conductive electrode pads E2 on the pad forming surfaces located opposite to the light emitting surfaces in contact with the first, second, and third wavelength converting elements 220, 320, and 420, respectively. The first LED chip 210, the second LED chip 310, and the third LED chip 410 can be individually driven when power is supplied from the outside through the first conductive electrode pads E1, the second conductive electrode pads E2, and solder bumps (not illustrated) connected thereto. The first conductive electrode pads E1 and the second conductive electrode pads E2 protrude from the lower surface of the light shield wall 100 so that they can be easily connected to bumps (not illustrated) connected to electrodes (not illustrated) on an external substrate (not illustrated).

The first LED chip 210, the second LED chip 310, and the third LED chip 410 include transparent semiconductor growth substrates 211, 311, and 411 and first conductive semiconductor layers 212, 312, and 412, active layers 213, 313, and 413, and second conductive semiconductor layers 214, 314, and 414 grown on the semiconductor growth substrates 211, 311, and 411, respectively. The transparent semiconductor growth substrates 211, 311, and 411 may be made of sapphire. The first conductive semiconductor layers 212, 312, and 412, the active layers 213, 313, and 413, and the second conductive semiconductor layers 214, 314, and 414 may be gallium nitride semiconductor layers grown on the sapphire substrates 211, 311, and 411, respectively. The first conductive semiconductor layers 212, 312, and 412 may be n-type semiconductor layers and the second conductive semiconductor layers 214, 314, and 414 may be p-type semiconductor layers. The active layers 213, 313, and 413 may include multi-quantum wells.

The first light transmitting member 230, the second light transmitting member 330, and the third light transmitting member 430 are accommodated in the first vertical hole 101, the second vertical hole 102, and the third vertical hole 103 of the light shield wall 100, respectively, and are in contact with the inner wall surfaces of the light shield wall 100. Thus, the first light transmitting member 230, the second light transmitting member 330, and the third light transmitting member 430 are isolated from one another. The first, second, and third wavelength converting members 220, 320, and 420 and the transparent semiconductor growth substrates 211, 311, and 411 of the first, second, and third LED chips 210, 310, and 410 are accommodated in the first vertical hole 101, the second vertical hole 102, and the third vertical hole 103 of the light shield wall 100, respectively, and are in contact with the inner wall surfaces of the light shield wall 100. Thus, the first, second, and third wavelength converting members 220, 320, and 420 are isolated from one another and the transparent semiconductor growth substrates 211, 311, and 411 are isolated from one another. Due to this construction, red light, green light, and blue light can be emitted from the first, second, and third light emitting units 200, 300, and 400 without being mixed in the light shield wall 100, avoiding the need to employ complicated package structures or barriers. The light shield wall 100 may be formed by a black color body, as explained below.

As mentioned above, it is preferred that at least portions of the side surfaces of the transparent semiconductor growth substrates 211, 311, and 411 are in contact with the inner side surfaces of the light shield wall 100 and the side surfaces of some or all of the first conductive semiconductor layers 212, 312, and 412, the active layers 213, 313, and 413, and the second conductive semiconductor layers 214, 314, and 414 are exposed to the outside without contact with the light shield wall 100. The exposure of at least portions of the first conductive semiconductor layers 212, 312, and 412, the active layers 213, 313, and 413, and the second conductive semiconductor layers 214, 314, and 414 from the light shield wall 100 can minimize loss of light resulting from the absorption of light by the light shield wall 100.

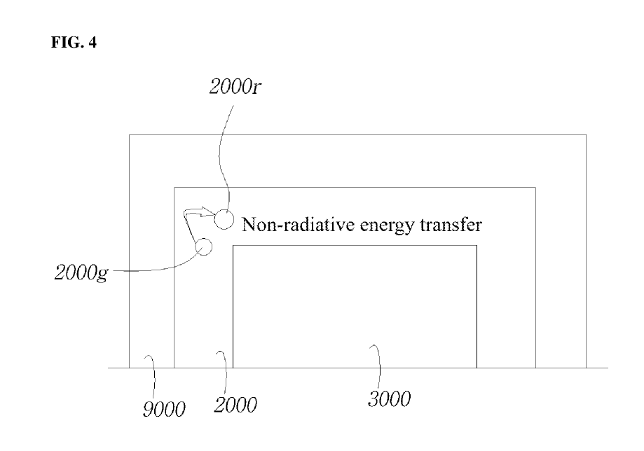

FIG. 4 illustrates a light emitting device according to another embodiment of the present invention.

Referring to FIG. 4, the light emitting device includes an LED chip 3000 outputting blue excitation light, a wavelength converting layer 200 covering the upper surface and the side surface of the LED chip 3000, and a light transmitting member 9000 covering the entire outer surface of the wavelength converting layer 2000. The wavelength converting layer 2000 includes first converting materials 2000g outputting light having a first peak intensity a1 (see FIG. 2) when excited alone by excitation light from the LED chip 3000 and second converting materials 2000r outputting light having a second peak intensity a2 when excited alone by excitation light from the LED chip 3000. The first converting materials 2000g are quantum dots capable of outputting light whose spectral distribution curve is shown as (a) in FIG. 2 when excited alone by the excitation light and the second converting materials 2000r are quantum dots capable of outputting light whose spectral distribution curve is shown as (b) in FIG. 2 when excited alone by the excitation light. However, it should be noted that the first converting materials 2000g and the second converting materials 2000r are not excited alone by the excitation light from the LED chip 3000 in view of the structure or state illustrated in FIG. 4. The spectral distribution curves (a) and (b) of FIG. 2 are obtained when the first converting materials only are used as wavelength converting materials and the second converting materials only are used as wavelength converting materials, respectively. The spectral distribution curve (c) of FIG. 2 is obtained when the first converting materials and the second converting materials are simultaneously used as wavelength converting materials, as illustrated in FIG. 4. These spectral distribution curves are obtained without the light transmitting member. Referring again to FIG. 4, the second converting materials 2000r absorb non-radiative energy from the first converting materials 2000g to output light having a third peak intensity a3 higher than the second peak intensity a2 when excited together with the first converting materials 2000g by the excitation light. The light transmitting member 9000 may be a DBR or color filter designed to selectively transmit only light in the wavelength region corresponding to the third peak intensity a3 among light having the spectral distribution curve (c) of FIG. 2 and to absorb light in the other wavelength regions without transmitting therethrough.

What is claimed is:

1. A light emitting device comprising: an LED chip outputting excitation light; first converting materials receiving the excitation light to output light having a first peak intensity; second converting materials receiving the excitation light to output light having a second peak intensity and absorbing non-radiative energy from the first converting materials to output light having a third peak intensity higher than the second peak intensity when excited together with the first converting materials by the excitation light; and a light transmitting member transmitting light in a wavelength region corresponding to the third peak intensity and blocking light in the other wavelength regions.

2. The light emitting device according to claim 1, wherein the first converting materials output light having a fourth peak intensity lower than the first peak intensity when excited together with the second converting materials by the excitation light.

3. The light emitting device according to claim 2, wherein the third peak intensity is higher than the fourth peak intensity.

4. The light emitting device according to claim 1, wherein the excitation light is UV or blue light and the first converting materials output blue or green light when excited by the excitation light.

5. The light emitting device according to claim 1, wherein the excitation light is UV or blue light and the second converting materials output red light when excited by the excitation light.

6. The light emitting device according to claim 1, wherein the first converting materials comprise donor quantum dots outputting green or blue light when excited by the excitation light and the second converting materials comprise acceptor quantum dots outputting red light when excited by the excitation light.

7. The light emitting device according to claim 6, wherein the distance between the donor quantum dots and the acceptor quantum dots is from 10 to 100 Å.

8. The light emitting device according to claim 1, wherein the first converting materials are mixed with the second converting materials in a light transmitting resin part.

9. The light emitting device according to claim 2, wherein the shift distance from a peak wavelength corresponding to the second peak intensity to a peak wavelength corresponding to the third peak intensity is between 5 nm and 15 nm.

10. The light emitting device according to claim 9, wherein the shift distance from the peak wavelength corresponding to the second peak intensity to the peak wavelength corresponding to the third peak intensity is at least 1.5 times smaller than that from a peak wavelength corresponding to the first peak intensity to a peak wavelength corresponding to the fourth peak intensity.

11. The light emitting device according to claim 2, wherein the difference between the first peak intensity and the fourth peak intensity is larger than that between the third peak intensity and the second peak intensity.

12. The light emitting device according to claim 1, further comprising: a reflector having a cavity in which the LED chip is accommodated; a wavelength converting panel comprising a lower glass plate, an upper glass plate, and a wavelength converting layer comprising the second converting materials and the first converting materials and interposed between the lower glass plate and the upper glass plate; and a sealing member disposed over the side surface of the lower glass plate and the side surface of the upper glass plate to connect the wavelength converting panel to the reflector.

13. The light emitting device according to claim 1, further comprising a light shield wall having a vertical hole wherein the LED chip is accommodated in a lower portion of the vertical hole and the wavelength converting layer comprising the mixture of the second converting materials and the first converting materials is arranged above the LED chip inside the vertical hole.

14. The light emitting device according to claim 1, further comprising a light shield wall having a vertical hole wherein the LED chip is accommodated in a lower portion of the vertical hole, the light transmitting member is arranged in an upper portion of the vertical hole, and the wavelength converting layer comprising the mixture of the second converting materials and the first converting materials is interposed between the LED chip and the light transmitting member inside the vertical hole.

15. The light emitting device according to claim 1, wherein the light transmitting member is a color filter absorbing or blocking light other than the light in the wavelength region corresponding to the third peak intensity.

16. A light emitting device comprising: an LED chip outputting excitation light; first converting materials receiving the excitation light to output light having a first peak intensity; and second converting materials receiving the excitation light to output light having a second peak intensity and absorbing non-radiative energy from the first converting materials to output light having a third peak intensity higher than the second peak intensity when excited together with the first converting materials by the excitation light, wherein the first converting materials output light having a fourth peak intensity lower than the first peak intensity when excited together with the second converting materials by the excitation light.

17. The light emitting device according to claim 16, further comprising a light transmitting member transmitting light in a wavelength region corresponding to the third peak intensity and absorbing or reflecting light in the other wavelength regions.

18. The light emitting device according to claim 16, wherein the third peak intensity is higher than the fourth peak intensity.

19. The light emitting device according to claim 16, wherein the excitation light is UV or blue light and the first converting materials output blue or green light when excited by the excitation light.

20. The light emitting device according to claim 16, wherein the excitation light is UV or blue light and the second converting materials output red light when excited by the excitation light.
